(19) United States
(12) Patent Application Publication
(10) Pub. No.: US 2007/0069316 A1
(43) Pub. Date: Mar. 29, 2007

(54) Image sensor having dual gate pattern and method of manufacturing the same

(75) Inventor: Sang-min Lee, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/527,605

(22) Filed: Sep. 27, 2006

(30) Foreign Application Priority Data
Sep. 27, 2005 (KR) 10-2005-0089987

(51) Int. Cl. H01L 27/14

(52) U.S. Cl. 257/431

(57) ABSTRACT

An image sensor capable of improving the performance of a transistor of a peripheral circuit region while maintaining high picture quality, and a method of manufacturing the same are disclosed. The image sensor may include a semiconductor substrate having an active pixel region and a peripheral circuit region, a first gate pattern formed on the semiconductor substrate in the active pixel region, and a second gate pattern formed on the semiconductor substrate in the peripheral circuit region and made of a second material layer. The second gate pattern may also include the first material layer.

### PRIORITY STATEMENT

This application claims priority under 35 U.S.C. § 119(a) to Korean Patent Application No. 10-2005-0089987, filed on Sep. 27, 2005 in the Korean Intellectual Property Office (KIPO), the entire contents are herein incorporated by reference.

### BACKGROUND

1. Field

Example embodiments relate to an image sensor and a method of manufacturing the same. Other example embodiments relate to a CMOS image sensor and a method of manufacturing the same.

2. Description of the Prior Art

An image sensor is a device that converts optical images to electrical signals. With the development of the computer and the communication industry, the demand for an image sensor having improved performance has increased and many devices (e.g., digital cameras, camcorders, PCSs (Personal Communication Systems), video game machines, security cameras, micro-cameras for medical applications, and/or robots) have image sensors. To conform with the advancement of chip manufacturing technique associated with system LSI (large scale integration), in a semiconductor integrated circuit device which embodies an image sensor, a peripheral circuit region having analog circuits and an active pixel region having image sensing circuits may be formed on the same semiconductor substrate.

In line with other semiconductor integrated circuits, the design rule in the manufacture of an image sensor may be shrinking. A transistor, which constitutes a semiconductor integrated circuit, may be required to perform at a higher level. There has been research regarding a transistor (e.g., metal gate transistor) that may perform at a higher level while satisfying a design rule which is shrinking. When compared to the conventional configuration which may use a polysilicon layer or a polysilicon layer with a tungsten silicide layer deposited thereon, the metal gate, which decreases the resistance of a transistor and increases the speed thereof, may not be as thick as the conventional configuration. The metal gate may have various problems impeding application to an active pixel region (e.g., a white defect, a dark current and/or dark current noise, and/or other defects). Due to the metal gate being relatively thin, it may be more difficult to form a photodiode in the active pixel region in a self-aligned manner.

### SUMMARY

Example embodiments relate to an image sensor and a method of manufacturing the same. Other example embodiments relate to a CMOS image sensor and a method of manufacturing the same. Example embodiments provide an image sensor which may improve the performance of a transistor while maintaining higher picture quality and a method of manufacturing the same. Example embodiments also provide a method of manufacturing an image sensor that may improve the performance of a transistor while maintaining higher picture quality.

According to example embodiments, an image sensor may include a semiconductor substrate having an active pixel region and a peripheral circuit region, a first gate pattern formed on the semiconductor substrate in the active pixel region and including a first material layer and a second gate pattern formed on the semiconductor substrate in the peripheral circuit region and including a second material layer. The second gate pattern may also include the first material layer. The first material layer may include a polysilicon layer and the second material layer may include a metal layer. The first gate pattern may have a thickness which is greater than that of the second gate pattern. The metal layer may be one selected from the group including a tungsten layer, a tantalum layer, a titanium layer, a cobalt layer, a nickel layer, a platinum layer and mixtures thereof.

A first gate insulation layer pattern may be formed between the first gate pattern and the semiconductor substrate and a second gate insulation layer pattern may be formed between the second gate pattern and the semiconductor substrate. The first gate insulation layer pattern may include a silicon oxide layer or a silicon oxynitride layer and the second gate insulation layer pattern may include a high-k oxide layer. The high-k oxide layer may be one selected from the group including a tantalum oxide layer (TaO), an aluminum oxide layer (AlO), a hafnium oxide layer (HfO) and a laminate thereof. The first and second gate insulation layer patterns may be made of the same material. The first and second gate insulation layer patterns may include a silicon oxide layer, a silicon oxynitride layer or a high-k oxide layer. The second gate insulation layer pattern may have a thickness which is greater than that of the first gate insulation layer pattern.

According to other example embodiments, a method of manufacturing an image sensor may include providing a semiconductor substrate having an active pixel region and a peripheral circuit region, forming a first gate pattern including a first material layer on the semiconductor substrate in the active pixel region and forming a second gate pattern including a second material layer on the semiconductor substrate in the peripheral circuit region. The second gate pattern may also include the first material layer. The method may further include forming a photodiode at one side of the first gate pattern.

### BRIEF DESCRIPTION OF THE DRAWINGS

Example embodiments will be more clearly understood from the following detailed description taken in conjunction with the accompanying drawings. FIGS. 1-5G represent non-limiting, example embodiments as described herein.

FIG. 1 is a diagram illustrating an image sensor according to example embodiments;

FIG. 2 is a diagram of the line A-A′ of FIG. 1, illustrating an image sensor according to example embodiments;

FIGS. 3A-3F are diagrams illustrating a method of manufacturing the image sensor according to example embodiments;

FIG. 4 is a diagram of the line A-A′ of FIG. 1, illustrating an image sensor according to example embodiments; and

FIGS. 5A-5G are diagrams explaining a method of manufacturing the image sensor according to example embodiments.

### DETAILED DESCRIPTION OF EXAMPLE EMBODIMENTS

The advantages and features of example embodiments and the method of attaining those advantages and features will be clearly appreciated by referring to the embodiments described below with reference to the accompanying drawings. However, it should be understood that example embodiments are not limited to the following embodiments and may be realized as various different configurations. The following embodiments are provided only to make the disclosure of example embodiments adequate and to notify a person having ordinary skill in the art of the scope of example embodiments which is defined by the attached claims. Therefore, in the following embodiments, well-known process steps, well-known device structures and other well-known techniques will not be concretely described so as to avoid rendering example embodiments unclear. The example embodiments described and exemplified below must be interpreted to include complementary embodiments. In the following descriptions, the same reference numerals will be used throughout the drawings and the descriptions to refer to the same or like parts.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Each of the image sensors, according to example embodiments, may include a CCD (charged coupled device) and a CMOS image sensor. While the CCD has a lower noise level and higher picture quality when compared to the CMOS image sensor, it may be more costly and require a higher voltage. The CMOS image sensor may have a simpler driving scheme, and may be embodied to use various scanning schemes. Because a signal processing circuit may be integrated into a single chip, miniaturization of a product may be possible. Because it may be compatible with CMOS manufacturing process techniques, the manufacturing cost thereof may be decreased. Further, because the CMOS image sensor has a lower power consumption level, it may be more easily applied to a product which has a limited battery capacity. Consequently, in the following descriptions, the image sensor, according to example embodiments, may include a CMOS image sensor. Of course, it is to be understood that the technical concepts of example embodiments may be applied to a CCD in the same manner.

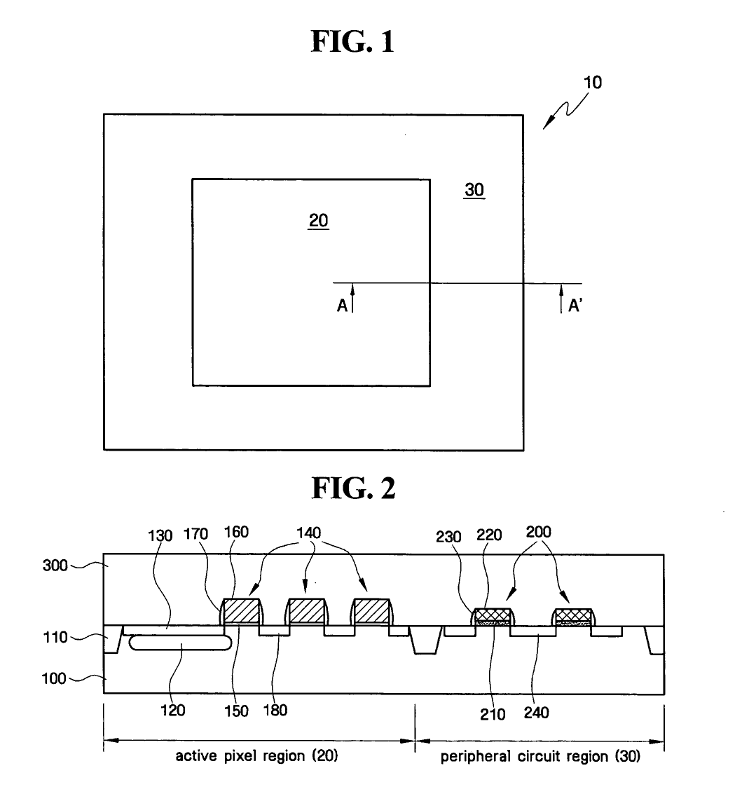

Example embodiments relate to an image sensor and a method of manufacturing the same. Other example embodiments relate to a CMOS image sensor and a method of manufacturing the same. FIG. 1 is a diagram illustrating an image sensor according to example embodiments. Referring to FIG. 1, the image sensor 10, according to example embodiments, may be composed of an active pixel region 20 and a peripheral circuit region 30. The active pixel region 20 may include a plurality of unit pixels which are arranged in a matrix. Each of the plurality of unit pixels may function to convert an optical image to an electrical signal. Each unit pixel may include a photodiode, a transfer gate, a reset gate, a selection gate, a drive gate and/or any other suitable materials. The peripheral circuit region 30 may be composed of digital circuits (e.g., a timing generator, a row decoder, a row driver, a latch, a column decoder and/or any other suitable digital circuit) and/or analog circuits (e.g., a correlated double sampler (CDS), an analog-to-digital converter (ADC) and/or any other suitable analog circuit).

The timing generator may provide a timing signal and a control signal to the row decoder and the column decoder. The row driver may provide a plurality of drive signals to the active pixel region 20 to conform with the decoding results from the row decoder. When the unit pixels are arranged in a matrix, the drive signals may be provided for each column. The correlated double sampler may receive electrical signals via vertical signal lines created in the active pixel region 20, hold the electrical signals, and/or perform a sampling function. The correlated double sampler may sample a specific reference voltage (hereinafter, referred to as a “noise level”) and a signal voltage (hereinafter, referred to as a “signal level”) by the created electrical signal and output the difference between the noise level and the signal level. The analog-to-digital converter may convert the analog signal, corresponding to the difference, into a digital signal and then output the digital signal. The latch may latch the digital signal and the latched signals may sequentially output to an image signal processor to conform with the decoding results from the column decoder.

FIG. 2 is a diagram of line A-A′ of FIG. 1, illustrating an image sensor according to example embodiments. A device isolation layer 110 may be formed on a semiconductor substrate 100 that has the active pixel region 20 and the peripheral circuit region 30 to isolate an active region from a field region. A photodiode 120 may be formed on the semiconductor substrate 100 in the active pixel region 20 at a given depth. The photodiode 120 may receive external light, may convert the external light into an electrical signal and/or may store the converted electrical signal. Because an electron is used as a signal transmitting charge which is generated in proportion to the intensity of the light, the photodiode 120 may be formed as an N-type photodiode.

A hole accumulation device (HAD) area 130 may be formed on the photodiode 120. The HAD area 130 functions to offset defects (e.g., a dangling bond) existing on the surface of the semiconductor substrate 100 and to thereby reduce a dark current, and others. First gates 140 may be formed at one side of the photodiode 120 and the HAD area 130. For example, the first gates 140 may be transfer gates which are formed on the semiconductor substrate 100 adjacent to the photodiode 120. The first gates 140 may include a reset gate, a drive gate, a selection gate and/or any other suitable gate which are sequentially formed at regular intervals. Each of the first gates 140 may be composed of a first gate insulation layer pattern 150 and a first gate pattern 160. The first gate insulation layer pattern 150 may include a silicon oxide layer and/or a silicon oxynitride layer. For example, the first gate insulation layer pattern 150 may have a thickness in the range of about 30 Å to about 70 Å.

The first gate pattern 160 may include a polysilicon layer. For example, the first gate pattern 160 may have a thickness in a range of about 850 Å to about 1,500 Å. A spacer 170 may be formed on at least one side surface of the first gate 140 which is composed of the first gate insulation layer pattern 150 and the first gate pattern 160. For example, the spacer 170 may include a silicon nitride layer. Source or drain regions 180 may be formed to a given depth on the semiconductor substrate 100 between two adjoining first gates 140. As described above, the peripheral circuit region 30 may be composed of a digital area (not shown) having digital circuits and an analog area (not shown) having analog circuits, each circuit including an N-type transistor and/or a P-type transistor.

Second gates 200 may be formed on the semiconductor substrate 100 in the peripheral circuit region 30. Each of the second gates 200 may be composed of a second gate insulation layer pattern 210 and a second gate pattern 220. The second gate insulation layer pattern 210 may include a high-k oxide layer. The high-k oxide layer may be a tantalum oxide layer (TaO), an aluminum oxide layer (AlO), a hafnium oxide layer (HfO) and/or a laminate thereof. For example, the second gate insulation layer pattern 210 may have a thickness of about 60 Å to 200 Å, which is about two to three times greater than that of the first gate insulation layer pattern 150. The second gate pattern 220 may include a metal layer. The metal layer may be one selected from the group including a tungsten layer, a tantalum layer, a titanium layer, a cobalt layer, a nickel layer, a platinum layer, and/or mixtures thereof. For example, the second gate pattern 220 may have a thickness in a range of about 300 Å to about 800 Å. Accordingly, the first gate pattern 160 may be thicker than the second gate pattern 220 by a factor of about 1.2 to 2.

A spacer 230 may be formed on at least one side surface of the second gate 200 which is composed of the second gate insulation layer pattern 210 and the second gate pattern 220. Source or drain regions 240 may be formed to a given depth on the semiconductor substrate 100 between two adjoining second gates 200. An interlayer insulation layer 300 may be formed on the semiconductor substrate 100 to cover the first gates 140 and the second gates 200. A plurality of wiring layers (not shown) may be formed in the interlayer insulation layer 300, and a color filter layer (not shown) and a micro-lens (not shown) may be additionally formed on the interlayer insulation layer 300. Due to the presence of the first gate patterns 160, which includes a polysilicon layer formed in the active pixel region 20 to a thickness in a range of about 850 Å to about 1,500 Å, the photodiode 120 and the HAD area 130 may be formed to be self-aligned with the first gate patterns 160. Due to the presence of the second gate patterns 220, each of which includes a metal layer formed in the peripheral circuit region 30, the performance of transistors may be improved.

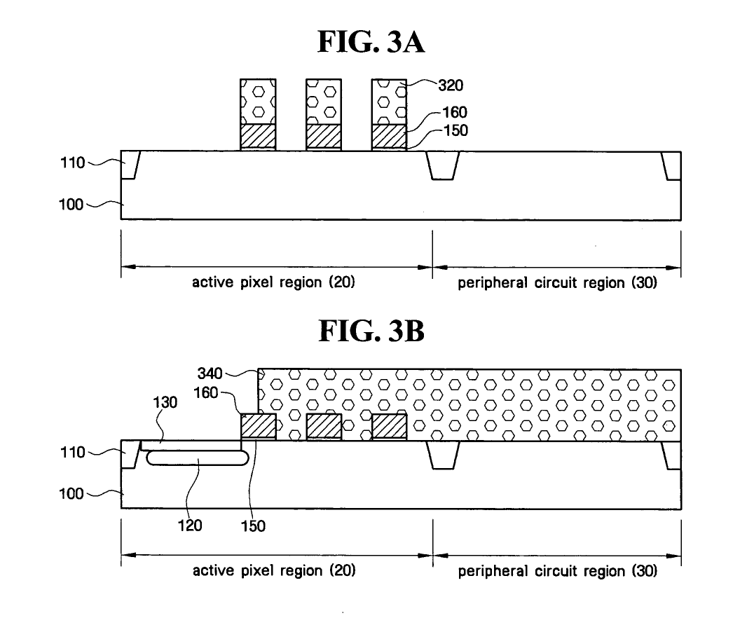

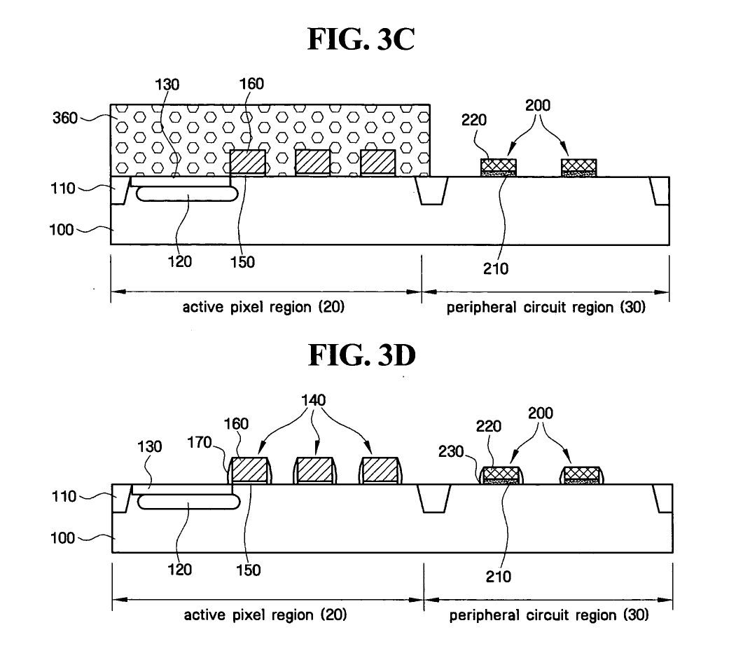

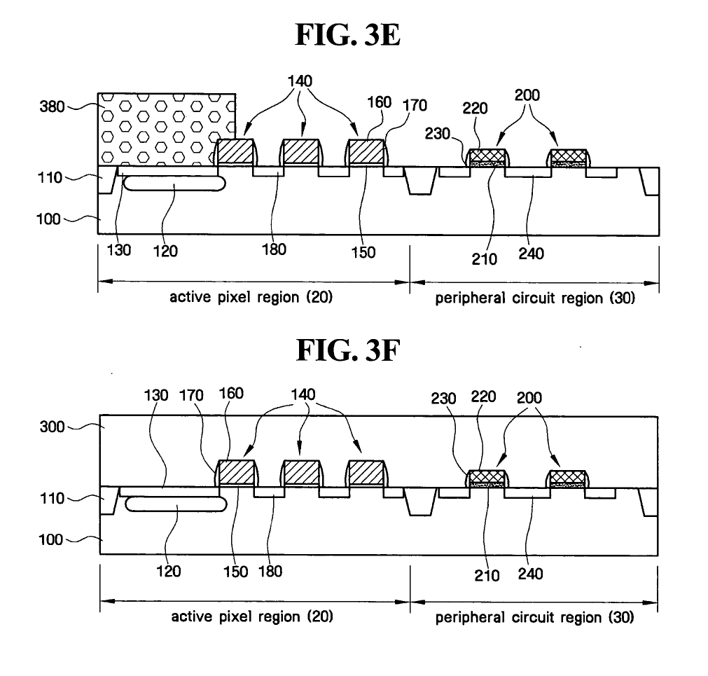

FIGS. 3A-3F are diagrams illustrating a method of manufacturing the image sensor according to example embodiments. Referring to FIG. 3A, the device isolation layer 110 may be formed on the semiconductor substrate 100, which is composed of the active pixel region 20 and the peripheral circuit region 30, to isolate the active region from the field region. The device isolation layer 110 may be formed by etching a given portion of the semiconductor substrate 100 and burying an insulation material in the etched portion, or by performing an oxidizing process for the given portion of the semiconductor substrate 100. A first insulation layer and a first gate layer may be formed on the semiconductor substrate 100. For example, after the first insulation layer is formed as a silicon oxide layer and/or a silicon oxynitride layer with a thickness in a range of about 30 Å to about 70 Å, the first gate layer may be formed as a polysilicon layer to have a thickness of about 850 Å to about 1,500 Å. By patterning the first gate layer and the first insulation layer through a photolithographic process using a first photoresist pattern 320, the first gate pattern 160 and the first gate insulation layer pattern 150 may be formed in the active pixel region 20.

Referring to FIG. 3B, using a second photoresist pattern 340 which covers the entire peripheral circuit region 30 and the active pixel region 20, excluding the portion on which the photodiode is to be formed, the photodiode 120 and the HAD area 130 may be formed in the semiconductor substrate 100 due to the first gate pattern 160 which is adjacent to the portion of the active pixel region 20 on which the photodiode is to be formed. By implanting impurity ions (not shown) of phosphorus (P) or arsenic (As), the photodiode 120 having an N-type conductive layer may be formed in the semiconductor substrate 100 at a given depth. By implanting ions (not shown) of boron (B) or boron difluoride (BF₂) in the surface of the semiconductor substrate 100 over the photodiode 120 formed as described above, the HAD area 130 having a P-type conductive layer may be formed. Although a separate ion implantation mask may be employed, the second photoresist pattern 340 may be used to conduct the process.

Referring to FIG. 3C, with the active pixel region 20 covered by a third photoresist pattern 360, the second gates 200 may be formed in the peripheral circuit region 30. In place of the third photoresist pattern 360, a hard mask layer (e.g., an oxide layer and/or any other suitable layer) may be used. A second insulation layer and a second gate layer may be deposited on the semiconductor substrate 100. For example, after the second insulation layer is formed as a high-k oxide layer which is selected from the group including a tantalum oxide layer (TaO), an aluminum oxide layer (AlO), a hafnium oxide layer (HfO), and/or a laminate thereof and has a thickness in a range of about 60 Å to about 200 Å, the second gate layer may be formed as a metal layer with a thickness in a range of about 300 Å to about 800 Å. The metal layer may be one selected from the group including a tungsten layer, a tantalum layer, a titanium layer, a cobalt layer, a nickel layer, a platinum layer and/or mixtures thereof. By patterning the second gate layer and the second insulation layer through a photolithographic process, the second gate pattern 220 and the second gate insulation layer pattern 210 may be formed in the peripheral circuit region 30.

Referring to FIG. 3D, by depositing and etching an insulation layer (not shown), for example, a nitride layer, on the entire surface of the semiconductor substrate 100, the spacers 170 and 230 may be formed. For example, the spacers 170 of the active pixel region 20 and the spacers 230 of the peripheral circuit region 30 may be formed at the same time or at different times.

Referring to FIG. 3E, after a fourth photoresist pattern 380 is formed on the photodiode 120 and a portion of the gate 140 which is adjacent to the photodiode 120 in the active pixel region 20, by implanting impurity ions, the source or drain regions 180 and 240 may be formed in the semiconductor substrate 100 on the sides of the respective gates 140 and 200. For example, the N-type source/drain regions may be formed in a manner where after lightly doped areas (not shown) having N-type conductive layers are formed by implanting impurity ions (not shown) of phosphorus (P) or arsenic (As) having a concentration of about 1E¹³ to 5E¹⁴ atoms/cm², heavily doped areas (not shown) having N-type conductive layers may be formed by implanting impurity ions (not shown) of phosphorus (P) or arsenic (As) having a concentration of about 1E¹⁵ to 9E¹⁵ atoms/cm². In the areas on which P-type transistors are to be formed, by implanting impurity ions (not shown) of boron (B) and/or boron difluoride (BF₂), lightly doped areas (not shown) and heavily doped areas may be sequentially formed.

Referring to FIG. 3F, the interlayer insulation layer 300 may be formed on the semiconductor substrate 100 to cover the first gates 140 and the second gates 200. At least one wiring layer (not shown) may be formed in the interlayer insulation layer 300, and the color filter layer (not shown) and the micro-lens (not shown) may be additionally formed on the interlayer insulation layer 300.

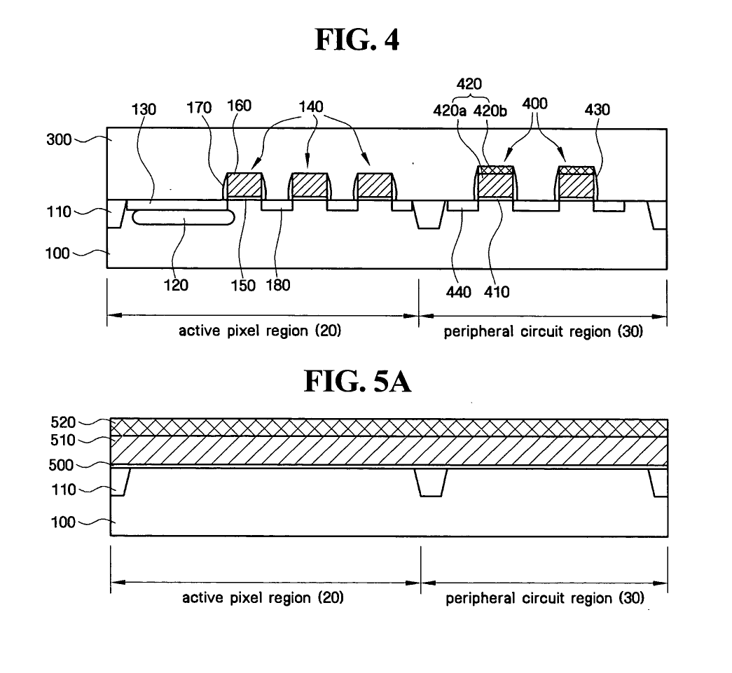

FIG. 4 is a diagram of line A-A′ of FIG. 1, illustrating an image sensor according to example embodiments. As described above, the peripheral circuit region 30 may be composed of a digital area (not shown) having digital circuits and an analog area (not shown) having analog circuits, and each circuit may include an N-type transistor or a P-type transistor. Second gates 400 may be formed on the semiconductor substrate 100 in the peripheral circuit region 30. Each of the second gates 400 may be composed of a second gate insulation layer pattern 410 and a second gate pattern 420. The second gate insulation layer pattern 410 may include a silicon oxide layer and/or a silicon oxynitride layer. For example, the second gate insulation layer pattern 410 may have a thickness in a range of about 30 Å to about 70 Å. Further, the second gate insulation layer pattern 410 may be made of the same material as the first gate insulation layer pattern 150. For example, the first and second gate insulation layer patterns 150 and 410 may include a silicon oxide layer, a silicon oxynitride layer and/or a high-k oxide layer.

The high-k oxide layer may be selected from the group including a tantalum oxide layer (TaO), an aluminum oxide layer (AlO), a hafnium oxide layer (HfO) and/or a laminate thereof. The second gate pattern 420 may be composed of a first material layer 420a and a second material layer 420b. In example embodiments, the second gate pattern and the first gate pattern may include the same material, but may not be formed simultaneously. For example, the first material layer 420a may include a polysilicon layer. The polysilicon layer may be formed in the same manner as the first gate pattern 160 which is formed in the active pixel region 20. The second material layer 420b may include a metal layer. For example, the metal layer may be one selected from the group including a tungsten layer, a tantalum layer, a titanium layer, a cobalt layer, a nickel layer, a platinum layer and/or mixtures thereof. For example, the second material layer 420b may have a thickness in a range of about 300 Å to about 800 Å. As described above, due to the fact that the first material layer 420a of the second gate pattern 420 is formed as a polysilicon layer which has the same work function as the first gate pattern 160 of the active pixel region 20, the first gate insulation layer pattern 150 and the second gate insulation layer pattern 410 may be formed using the same gate insulation layer, whereby the process may be simplified.

A spacer 430 may be formed on at least one side surface of the second gate 400 which is composed of the second gate insulation layer pattern 410 and the second gate pattern 420. Source or drain regions 440 may be formed to a given depth on the semiconductor substrate 100 between two adjoining second gates 400.

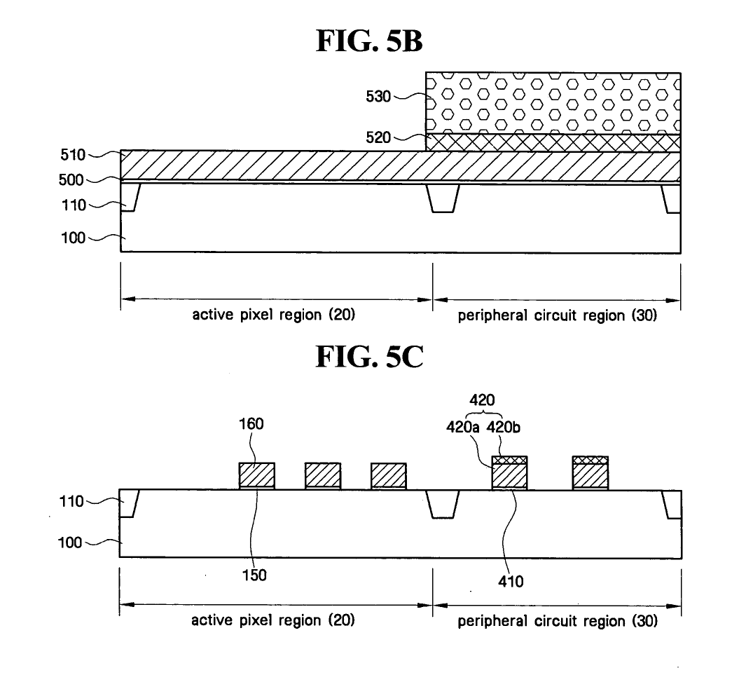

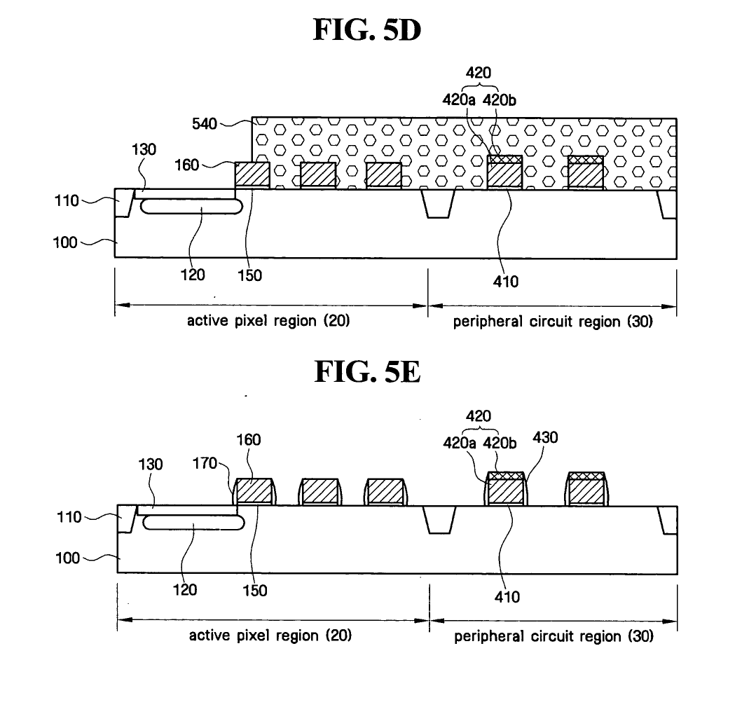

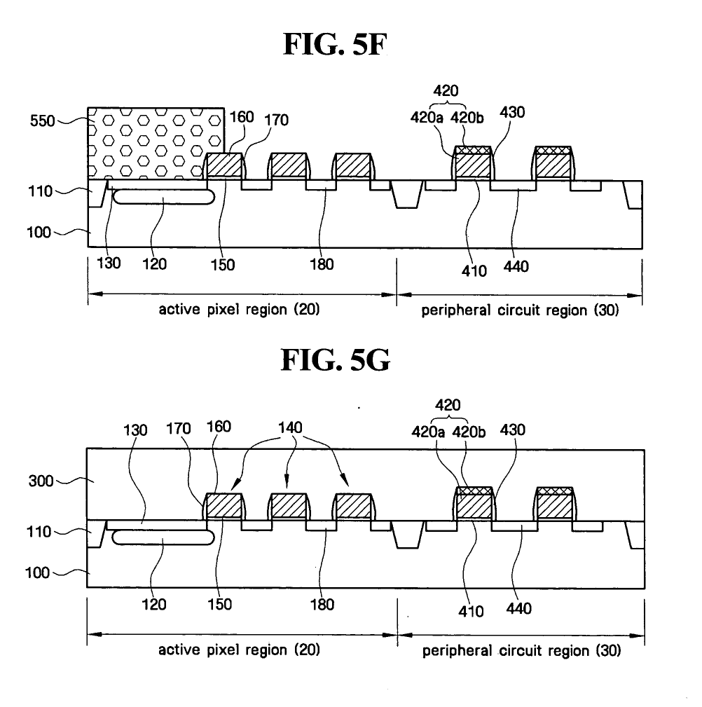

FIGS. 5A-5G are diagrams illustrating the method of manufacturing the image sensor according to example embodiments. Referring to FIG. 5A, a gate insulation layer 500, a polysilicon layer 510 and a metal layer 520 may be sequentially formed on the semiconductor substrate 100 which is formed with the device isolation layer 110. The gate insulation layer 500 may include a silicon oxide layer, a silicon oxynitride layer and/or a high-k oxide layer. For example, a high-k oxide layer, which is selected from the group including a tantalum oxide layer (TaO), an aluminum oxide layer (AlO), a hafnium oxide layer (HfO) and/or combinations thereof, may be formed to have a thickness in a range of about 60 Å to about 200 Å. For example, the polysilicon layer 510 may be formed to have a thickness in a range of about 850 Å to about 1,500 Å. The metal layer 520 may be formed to have a thickness in a range of about 300 Å to about 800 Å.

Referring to FIG. 5B, the peripheral circuit region 30 may be covered by a fifth photoresist pattern 530 and the second material layer 520, which is formed in the active pixel region 20, may be removed. Referring to FIG. 5C, after removing the fifth photoresist pattern 530 through a photolithographic process, the first gate insulation layer pattern 150 and the first gate pattern 160 may be formed in the active pixel region 20, and the second gate insulation layer pattern 410 and the second gate pattern 420 may be formed in the peripheral circuit region 30. For example, the first and second gate patterns 160 and 420 maybe simultaneously formed using the same photolithographic process.

Referring to FIG. 5D, using a sixth photoresist pattern 540, which covers the entire peripheral circuit region 30 and the active pixel region 20 excluding the portion on which the photodiode is to be formed, and the first gate pattern 160, which is adjacent to the portion of the active pixel region 20 on which the photodiode is to be formed, the photodiode 120 and the HAD area 130 may be formed in the semiconductor substrate 100. First, by implanting impurity ions (not shown) of phosphorus (P) or arsenic (As), the photodiode 120 having an N-type conductive layer may be formed in the semiconductor substrate 100 at a given depth. Then, by implanting ions (not shown) of boron (B) or boron difluoride (BF₂) in the surface of the semiconductor substrate 100 over the photodiode 120 formed as described above, the HAD area 130 having a P-type conductive layer may be formed. While a separate ion implantation mask may be employed, the sixth photoresist pattern 540 may conduct a process.

Referring to FIG. 5E, by depositing and etching an insulation layer (not shown), for example, a nitride layer, over the entire surface of the semiconductor substrate 100, the spacers 170 and 430 may be formed. For example, the spacers 170 of the active pixel region 20 and the spacers 430 of the peripheral circuit region 30 may or may not be formed simultaneously.

Referring to FIG. 5F, after a seventh photoresist pattern 550 is formed on the photodiode 120 and a portion of the gate 140 which is adjacent to the photodiode 120 in the active pixel region 20, by implanting impurity ions, the source or drain regions 180 and 440 may be formed in the semiconductor substrate 100 at sides of the respective gates 140 and 400. For example, the N-type source/drain regions may be formed in a manner such that, after lightly doped areas (not shown) having N-type conductive layers are formed by implanting impurity ions (not shown) of phosphorus (P) or arsenic (As) having a concentration of about 1E¹³ to 5E¹⁴ atoms/cm², heavily doped areas (not shown) having N-type conductive layers are formed by implanting impurity ions (not shown) of phosphorus (P) or arsenic (As) having a concentration of about 1E¹⁵ to 9E¹⁵ atoms/cm². In the areas on which P-type transistors are to be formed, by implanting impurity ions (not shown) of boron (B) or boron difluoride (BF₂), lightly doped areas (not shown) and heavily doped areas may be sequentially formed.

Referring to FIG. 5G, the interlayer insulation layer 300 may be formed on the semiconductor substrate 100 to cover the first gates 140 and the second gates 400. At least one wiring layer (not shown) may be formed in the interlayer insulation layer 300 and the color filter layer (not shown) and the micro-lens (not shown) may be additionally formed on the interlayer insulation layer 300.

Although example embodiments have been described for illustrative purposes, those skilled in the art will appreciate that various modifications, additions and substitutions are possible, without departing from the scope and spirit of the accompanying claims. As is apparent from the above descriptions, the image sensor and the method of manufacturing the same, according to example embodiments, may improve the performance of a peripheral circuit region while maintaining higher picture quality.

What is claimed:

1. An image sensor comprising:
a semiconductor substrate having an active pixel region and a peripheral circuit region;
a first gate pattern formed on the semiconductor substrate in the active pixel region and including a first material layer; and
a second gate pattern formed on the semiconductor substrate in the peripheral circuit region and made of a second material layer.

2. The image sensor of claim 1, wherein the second gate pattern includes the first material layer.

3. The image sensor of claim 1, wherein the first material layer includes a polysilicon layer, and the second material layer includes a metal layer.

4. The image sensor of claim 3, wherein the first gate pattern has a thickness which is greater than that of the second gate pattern.

5. The image sensor of claim 3, wherein the metal layer is one selected from the group including a tungsten layer, a tantalum layer, a titanium layer, a cobalt layer, a nickel layer, a platinum layer and mixtures thereof.

6. The image sensor of claim 1, further comprising:
a first gate insulation layer pattern formed between the first gate pattern and the semiconductor substrate; and
a second gate insulation layer pattern formed between the second gate pattern and the semiconductor substrate.

7. The image sensor of claim 6, wherein the first gate insulation layer pattern includes a silicon oxide layer or a silicon oxynitride layer and the second gate insulation layer pattern includes a high-k oxide layer.

8. The image sensor of claim 7, wherein the high-k oxide layer is one selected from the group including a tantalum oxide layer (TaO), an aluminum oxide layer (AlO), a hafnium oxide layer (HfO) and a laminate thereof.

9. The image sensor of claim 6, wherein the first and second gate insulation layer patterns are made of the same material.

10. The image sensor of claim 9, wherein the first and second gate insulation layer patterns include a silicon oxide layer, a silicon oxynitride layer or a high-k oxide layer.

11. The image sensor of claim 6, wherein the second gate insulation layer pattern has a thickness which is greater than that of the first gate insulation layer pattern.

12. A method of manufacturing an image sensor, comprising:
providing a semiconductor substrate having an active pixel region and a peripheral circuit region; and
forming a first gate pattern including a first material layer on the semiconductor substrate in the active pixel region and forming a second gate pattern including a second material layer on the semiconductor substrate in the peripheral circuit region.

13. The method of claim 12, wherein the second gate pattern includes the first material layer.

14. The method of claim 12, wherein the first material layer includes a polysilicon layer, and the second material layer includes a metal layer.

15. The method of claim 14, wherein the first gate pattern is formed to have a thickness which is greater than that of the second gate pattern.

16. The method of claim 12, further comprising:
forming a first gate insulation layer pattern between the first gate pattern and the semiconductor substrate; and
forming a second gate insulation layer pattern between the second gate pattern and the semiconductor substrate.

17. The method of claim 16, wherein the first gate insulation layer pattern includes a silicon oxide layer or a silicon oxynitride layer and a second gate insulation layer pattern includes a high-k oxide layer.

18. The method of claim 16, wherein the first and second gate insulation layer patterns are made of the same material.

19. The method of claim 18, wherein the first and second gate insulation layer patterns include a silicon oxide layer, a silicon oxynitride layer or a high-k oxide layer.

20. The method of claim 16, wherein the second gate insulation layer pattern is formed to a thickness which is greater than that of the first gate insulation layer pattern.

21. The method of claim 12, further comprising:
forming a photodiode at one side of the first gate pattern.
